(19) United States
(12) Patent Application Publication
(10) Pub. No.: US 2024/0297179 A1
(43) Pub. Date: Sep. 5, 2024

(54) DISPLAY APPARATUS

(71) Applicant: SAMSUNG ELECTRONICS CO., LTD., Suwon-si (KR)

(72) Inventors: Seungyong SHIN, Suwon-si (KR); Sungyeol KIM, Suwon-si (KR); Kyehoon LEE, Suwon-si (KR)

(73) Assignee: SAMSUNG ELECTRONICS CO., LTD., Suwon-si (KR)

(21) Appl. No.: 18/396,291

(22) Filed: Dec. 26, 2023

Related U.S. Application Data
(63) Continuation of application No. PCT/KR2023/020323, filed on Dec. 11, 2023.

(30) Foreign Application Priority Data
Mar. 2, 2023 (KR) 10-2023-0027895

(51) Int. Cl. H01L 27/12; H01L 25/16

(52) U.S. Cl. CPC H01L 27/124; H01L 25/167

(57) ABSTRACT

A display apparatus includes a substrate; a plurality of pixels arranged in a two-dimensional matrix on the substrate; a plurality of scan lines configured to be connected in the plurality of pixels; a scan driver Integrated Chip (IC) configured to transmit a scan signal to the plurality of scan lines, and including at least one first Thin Film Transistor (TFT); a plurality of data lines configured to be connected in the plurality of pixels; and a data driver IC configured to transmit a data signal to the plurality of data lines, and including at least one second TFT, wherein the first TFT and the second TFT may be different types.

### CROSS-REFERENCE TO RELATED APPLICATIONS

This application is a by-pass continuation of International Application No. PCT/KR2023/020323, filed on Dec. 11, 2023, which is based on and claims priority to Korean Patent Application No. 10-2023-0027895, filed on Mar. 2, 2023, in the Korean Intellectual Property Office, the disclosures of which are incorporated by reference herein in their entireties.

### BACKGROUND

### 1. Field

The disclosure relates to a display apparatus that uses a light emitting element to display an image.

### 2. Description of Related Art

In general, display apparatuses are a type of output devices for visually displaying obtained or stored image information to a user, and are used in various fields such as at home or in workplaces.

The display apparatuses may be classified into self-luminous displays where each pixel emits light by itself, and light-receiving displays that require a separate light source.

A Liquid Crystal Display (LCD) which is a representative light-receiving display includes a backlight unit that supplies light from the rear of a display panel, a liquid crystal layer that acts as a switch to pass/block light, and a color filter that changes the supplied light to the desired color. Accordingly, the LCD has a complex structure and has a limited implementation (e.g., small thickness).

On the other hand, a self-luminous display in which each pixel emits light by itself by including a light emitting element for each pixel does not require components such as a backlight unit and a liquid crystal layer and may exclude a color filter. Accordingly, the self-luminous display may have a simple structure and a high degree of design freedom. The self-luminous display may also realize thin thickness as well as excellent contrast ratio, brightness and viewing angle.

Among self-luminous displays, micro Light Emitting Diode (LED) displays are a type of flat panel display and includes a plurality of LEDs with a size of approximately 100 micrometers. Compared to LCDs requiring backlight, the micro LED displays may provide superior contrast, response time and energy efficiency.

In order to form an LED display on a substrate, a Thin Film Transistor (TFT), a data driver, and a scan driver are required to be formed on the substrate using a semiconductor process, and then LEDs are required to be mounted.

In existing LED displays, an active matrix method is used to form a TFT, and both data drivers and scan drivers are required to drive low currents. Accordingly, an amorphous silicon (a-Si) TFT process method is required to be used to allow both data driver and scan driver to drive low currents.

### SUMMARY

An aspect of the disclosure provides a display apparatus that may use different manufacturing processes for each of a data driver and a scan driver, thereby improving a driving efficiency of a light emitting element and reducing production complexity of the display apparatus.

In addition, the display apparatus may transmit/receive a signal using a multiplexer, thereby reducing the number of wirings on a substrate.

Technical aspects that can be achieved by the disclosure are not limited to the above-mentioned aspects, and other technical aspects not mentioned will be clearly understood by one of ordinary skill in the technical art to which the disclosure belongs from the following description.

According to an aspect of the disclosure, a display apparatus includes: a substrate: a plurality of pixels arranged in a two-dimensional matrix on the substrate; a plurality of scan lines connected to the plurality of pixels: a scan driver Integrated Chip (IC) configured to transmit a scan signal to the plurality of scan lines: a plurality of data lines connected to the plurality of pixels; and a data driver IC configured to transmit a data signal to the plurality of data lines, wherein the scan driver IC includes at least one first Thin Film Transistor (TFT), the data driver IC includes at least one second TFT, and the at least one first TFT and the at least one second TFT are different types.

The at least one first TFT may be configured to have a higher electron mobility than the at least one second TFT.

The at least one second TFT may be configured to have a higher accuracy in selecting a pixel among the plurality of pixels to supply a current than the at least one first TFT.

The at least one first TFT may include a Low-Temperature Polycrystalline Silicon (LTPS) TFT.

The at least one second TFT may include an Amorphous Silicon (a-Si) TFT.

Each pixel of the plurality of pixels may include at least three subpixels configured to output different colors, and the display apparatus may further include a multiplexer configured to transmit a signal from the data driver IC to at least one of the at least three subpixels of each pixel of the plurality of pixels via the plurality of data lines.

Each of the plurality of pixels may further include a red light emitting element, a green light emitting element, and a blue light emitting element.

According to an aspect of the disclosure, a display apparatus includes: a substrate: a plurality of pixels arranged in a two-dimensional matrix on the substrate, wherein each pixel of the plurality of pixels includes a plurality of subpixels configured to output different colors: a plurality of scan lines connected to the plurality of pixels: a scan driver Integrated Chip (IC) connected to the plurality of scan lines and configured to transmit a scan signal to the plurality of pixels via the plurality of scan lines: a plurality of data lines configured connected to the plurality of pixels; and a data driver IC connected to the plurality of data lines and configured to transmit a data signal to the plurality of pixels via the plurality of data lines, wherein the scan driver IC includes at least one first Thin Film Transistor (TFT), the data driver IC includes at least one second TFT, and the at least one first TFT and the at least one second TFT are different types.

The at least one first TFT may be configured to have a higher electron mobility than the at least one second TFT.

The at least one second TFT may be configured to have a higher accuracy in selecting a pixel among the plurality of pixels to supply a current than the at least one first TFT.

The at least one first TFT may include a Low-Temperature Polycrystalline Silicon (LTPS) TFT.

The at least one second TFT may include an Amorphous Silicon (a-Si) TFT.

The display apparatus may further include a multiplexer configured to transmit a signal from the data driver IC to at least one of the plurality of subpixels of each pixel of the plurality of pixels via the plurality of data lines.

Each of the plurality of pixels may further include a red light emitting element, a green light emitting element, and a blue light emitting element.

According to an aspect of the disclosure, a display apparatus includes: a substrate: a plurality of pixels arranged in a two-dimensional matrix on the substrate, wherein each pixel of the plurality of pixels includes a plurality of subpixels configured to output different colors: a plurality of scan lines connected to the plurality of pixels; a scan driver Integrated Chip (IC) connected to the plurality of scan lines and configured to transmit a scan signal to the plurality of pixels via the plurality of scan lines: a plurality of data lines configured connected to the plurality of pixels: a data driver IC connected to the plurality of data lines and configured to transmit a data signal to the plurality of pixels via the plurality of data lines; and a multiplexer configured to transmit a signal from the data driver IC to at least one of the plurality of subpixels of each pixel of the plurality of pixels via the plurality of data lines, wherein the scan driver IC includes at least one first Thin Film Transistor (TFT), the data driver IC includes at least one second TFT, and the at least one first TFT and the at least one second TFT are different types.

The at least one first TFT may be configured to have a higher electron mobility than the at least one second TFT.

The at least one second TFT may be configured to have a higher accuracy in selecting a pixel among the plurality of pixels to supply a current than the at least one first TFT.

The at least one first TFT may include a Low-Temperature Polycrystalline Silicon (LTPS) TFT.

The at least one second TFT may include an Amorphous Silicon (a-Si) TFT.

Each of the plurality of pixels may further include a red light emitting element, a green light emitting element, and a blue light emitting element.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates an appearance of a display apparatus according to an embodiment;

FIG. 2 is a perspective view illustrating an example of a display apparatus including a display module according to an embodiment:

FIG. 3 is a diagram illustrating an exemplary arrangement of pixels constituting a unit module of a display apparatus according to an embodiment:

FIG. 4 is a diagram illustrating a driver Integrated Chip (IC) deposited on a substrate according to an embodiment:

FIG. 5 is a control block diagram illustrating a display apparatus according to an embodiment:

FIGS. 6A and 6B are diagrams illustrating electron mobility depending on a Thin Film Transistor (TFT) manufacturing process according to an embodiment:

FIG. 7 is a diagram illustrating a connection relationship among a data driver, a scan driver, and a light emitting element according to an embodiment; and

FIG. 8 is a diagram illustrating a display apparatus including a multiplexer according to an embodiment.

### DETAILED DESCRIPTION

Embodiments described in the specification and configurations shown in the accompanying drawings are merely examples of the disclosure, and various modifications may replace the embodiments and the drawings of the disclosure at the time of filing of the application.

Also, like reference numerals or symbols denoted in the drawings of the specification represent members or components that perform the substantially same functions.

The terms used herein are only for the purpose of describing particular embodiments and are not intended to limit to the disclosure. A singular form of a noun corresponding to an item may include one item or a plurality of the items unless context clearly indicates otherwise. It will be understood that when the terms “include,” and/or “have,” when used in this specification, specify the presence of stated features, figures, steps, operations, components, members, or combinations thereof, but do not preclude the presence or addition of one or more other features, figures, steps, operations, components, members, or combinations thereof.

When it is said that one component is “coupled” or “connected” to another component, it means that one component can be directly or indirectly connected or coupled to the other component.

Also, it will be understood that, although the terms including ordinal numbers, such as “first”, “second”, etc., may be used herein to describe various components, these components should not be limited by these terms. These terms are only used to distinguish one component from another. For example, a first component could be termed a second component, and, similarly, a second component could be termed a first component, without departing from the scope of the disclosure. As used herein, the term “and/or” includes any and all combinations of one or more of associated listed items.

Herein, the expression “at least one of a, b or c” indicates “only a,” “only b,” “only c,” “both a and b,” “both a and c,” “both b and c,” or “all of a, b, and c.”

Hereinafter, embodiments of the disclosure are described in detail with reference to the accompanying drawings.

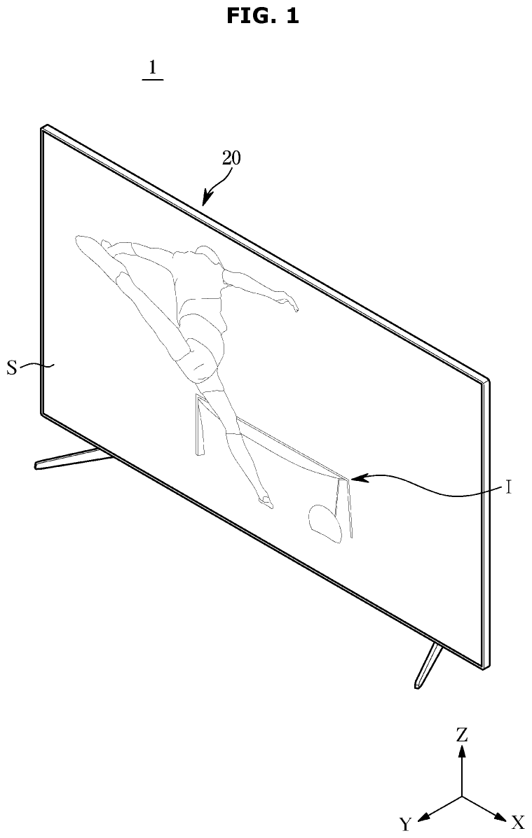

FIG. 1 illustrates an appearance of a display apparatus according to an embodiment.

A display apparatus is a device capable of processing an image signal received from the outside and visually displaying a processed image. Hereinafter, a case in which the display apparatus is a television (TV) is an example, but the disclosure is not limited thereto. For example, the display apparatus may be implemented in various forms, such as a monitor, a portable multimedia device, a portable communication device, and the like, and the form of the display apparatus is not limited as long as it is a device that visually displays an image.

In addition, the display apparatus may be a Large Format Display (LFD) installed outdoors, such as on a roof of a building or at a bus stop. The outdoors is not necessarily limited to the outdoors, and the display apparatus may be installed wherever a large number of people may enter and exit, even indoors such as at subway stations, shopping malls, movie theaters, office buildings, and stores.

The display apparatus may receive a video signal and an audio signal from various content sources, and output video and audio corresponding to the video signal and the audio signal, respectively. For example, the display apparatus may receive television broadcast content through a broadcast reception antenna or a wired cable, receive content from a content playback apparatus, or receive content from a content-providing server of a content provider.

The display apparatus may include a self-luminous display panel displaying an image using an element emitting light by itself. The self-luminous display panel may include a Light Emitting Diode (LED) panel. The display apparatus may also include a non-self-luminous display panel that transmits or blocks light emitted from a backlight unit to display an image. The non-self-luminous display panel may include a Liquid Crystal Display (LCD) panel, and the like.

As shown in FIG. 1, the display apparatus may include a body 20 including a plurality of components for displaying an image, and a screen S provided on one side of the body 20 to display an image I.

The body 20 forms an exterior of the display apparatus, and components of the display apparatus for displaying the image I may be provided inside the body 20. It is illustrated in FIG. 1 that the body 20 has a flat plate shape, but the shape of the body 20 is not limited to that shown in FIG. 1. For example, the body 20 may have a curved shape such that both left and right ends protrude forward and a center is concave.

The screen S is formed on a front surface of the body 20, and the image I, which is visual information, may be displayed on the screen S. For example, the screen S may display a still image or a video, as well as a two-dimensional (2D) plane image or a three-dimensional (3D) stereoscopic image.

The display apparatus may be implemented as a stand type, as shown in FIG. 1, or may be implemented as a wall-mounted type. In addition, as shown in FIG. 1, the display apparatus may be implemented in a rectangular shape where a width (a length in an Y-axis direction) is shorter than a height (a length in a Z-axis direction), may be implemented in a rectangular shape where the width is longer than the height, or may be implemented in a square shape. A manner of supporting the display apparatus and a shape of the display apparatus are not limited.

In the embodiment described below, a direction (+Y direction) in which an image is output is defined as a forward direction, and the opposite direction (−Y direction) is defined as a rear direction. In addition, an XYZ axis coordinate system is based on the display apparatus, and even in a case where the display apparatus is not upright as shown in FIG. 1 and is laid down, the coordinate system based on the display apparatus is not changed.

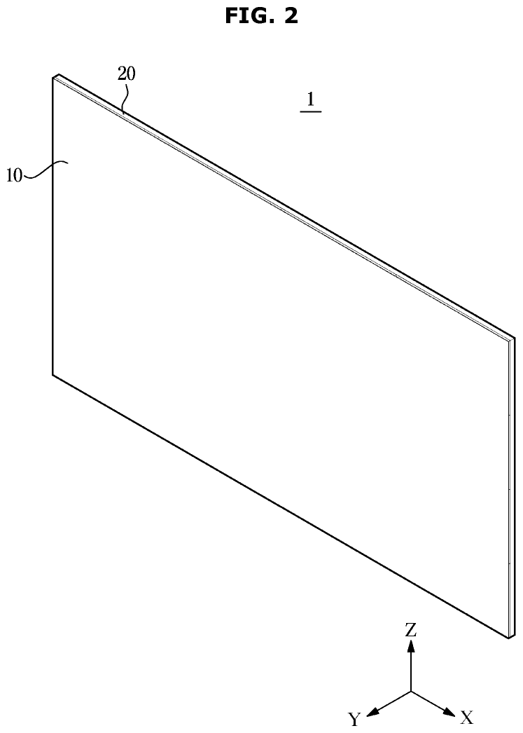

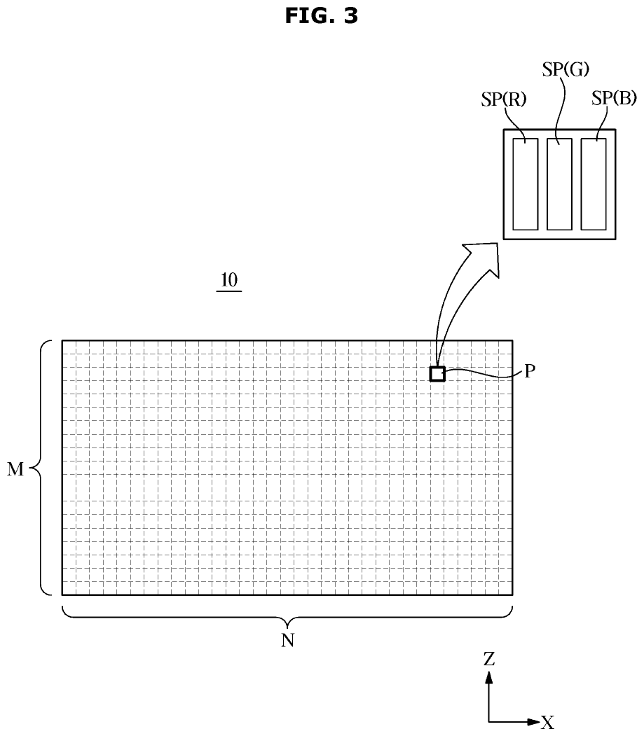

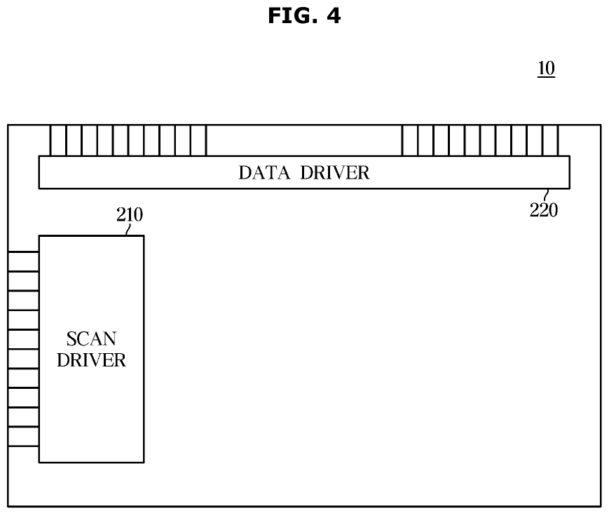

FIG. 2 is a perspective view illustrating an example of a display apparatus including a display module according to an embodiment. FIG. 3 is a diagram illustrating an example of arrangement of pixels constituting a unit module of a display apparatus according to an embodiment. FIG. 4 is a diagram illustrating a driver Integrated Chip (IC) deposited on a substrate according to an embodiment.

According to an embodiment, the display apparatus is a self-luminous display apparatus in which a light emitting element is disposed for each pixel and each pixel emits light by itself. Accordingly, the display apparatus does not require components such as a backlight unit, a liquid crystal layer, and the like, unlike an LCD device, and thus the display apparatus may have a thin thickness and a simple structure, thereby implementing various design changes.

In addition, the display apparatus according to an embodiment may employ an organic light emitting element such as an Organic LED (OLED), as a light emitting element disposed in each pixel. The display apparatus according to an embodiment may also employ an inorganic light emitting element such as an inorganic LED, as a light emitting element disposed in each pixel.

The light emitting element used in the display apparatus according to an embodiment may be a micro LED with a short side length of approximately 100 μm. As such, by employing micro LEDs, a pixel size may be reduced and a high resolution may be realized even in the same screen size.

In addition, by manufacturing LED chips in micro-scale, inorganic materials may be prevented from breaking when bent. In other words, by transferring a micro LED chip to a flexible substrate, the micro LED chip does not break even when the substrate is bent, and thus a flexible display apparatus may be realized.

The display apparatus employing a micro LED may be applied to various fields by utilizing ultra-small pixel size and thin thickness. For example, as shown in FIG. 2, a large screen may be implemented by tiling a plurality of display modules 10 onto which a plurality of micro LEDs are transferred and fixing to the body 20. Such a display apparatus with a large screen may be used as signage, electronic display board, and the like.

Meanwhile, the XYZ axis coordinate system shown in FIG. 2 is based on the display apparatus, and a plane on which the screen of the display apparatus 1 is located is an XZ plane, and a direction of image output or a direction of light emission of inorganic light emitting element is +Y direction. Because the coordinate system is based on the display apparatus 1, the same coordinate system may be applied both when the display apparatus 1 is laid down and upright.

In general, the display apparatus 1 is used in an upright position, and a user views an image from the front of the display apparatus 1. Accordingly, the +Y direction in which the image is output may be referred to as the front, and the opposite direction may be referred to as the rear.

In addition, the display apparatus 1 is generally manufactured in a laid state. Accordingly, the −Y direction of the display apparatus 1 may be referred to as a lower direction and the +Y direction may be referred to as an upper direction. That is, in the embodiment to be described below, the +Y direction may be referred to as the upper direction or the forward direction, and the −Y direction may be referred to as the lower direction or the rear direction.

Except for an upper surface and a lower surface of the flat-plane display apparatus 1 or display module 10, the remaining four surfaces are referred to as sides regardless of the posture of the display apparatus 1 or display module 10.

Although it is illustrated in FIG. 2 that the display apparatus 1 includes a single display module 10, the display apparatus 1 may implement a large screen by including a plurality of display modules, and thus the display apparatus 1 may be implemented as a TV, wearable device, portable device, personal computer (PC) monitor, and the like.

Referring to FIG. 3, the display module 10 may include an M×N (M, N are integers of 2 or more) arrangement of pixels, i.e., a plurality of pixels arranged in two dimensions. FIG. 3 conceptually shows a pixel arrangement, and thus the display module 10 may include a bezel area, wiring area, and the like, where no image is displayed, in addition to an active area where pixels are arranged.

In the embodiment, arranging components in two dimensions may include not only a case where the components are arranged on the same plane, but also a case where the components are arranged on different planes parallel to each other. In addition, in a case where components are arranged on the same plane, upper ends of the components are not necessarily to be located on the same plane, and may be located on different planes parallel to each other.

A pixel may include at least three subpixels that output light of different colors. For example, a unit pixel P may include three subpixels SP(R), SP(G), and SP(B) corresponding to red R, green G, and blue B, respectively. Here, the red subpixel SP(R) may output red light, the green subpixel SP(G) may output green light, and the blue subpixel SP(B) may output blue light.

However, the pixel arrangement in FIG. 3 is only an example applicable to the display module 10 and the display apparatus 1 according to an embodiment, and the subpixels may be arranged along the Z-axis direction or may not be arranged in a row. Also, sizes of subpixels may be implemented differently. A single pixel only requires to include a plurality of subpixels to implement a plurality of colors, and the size or arrangement of each subpixel are not limited.

In addition, the pixel P does not necessarily include only a red subpixel SP(R) outputting red light, a green subpixel SP(G) outputting green light, and a blue subpixel SP(B) outputting blue light. The pixel P may include subpixels that output yellow light or white light. That is, colors or types of light output from each subpixel or the number of subpixels are not limited.

However, in the embodiment to be described below, an example where the pixel P includes a red subpixel SP(R), green subpixel SP(G), and blue subpixel SP(B) is described.

As described above, the display module 10 and the display apparatus 1 according to an embodiment are a self-luminous display apparatus in which each pixel may emit light by itself. Accordingly, light emitting elements that emit light of different colors may be disposed in each subpixel. For example, a red light emitting element may be disposed in a red subpixel SP(R), a green light emitting element may be disposed in a green subpixel SP(G), and a blue light emitting element may be disposed in a blue sub-pixel SP(B).

Accordingly, in the embodiment, the pixel P may represent a cluster including the red light emitting element, the green light emitting element, and the blue light emitting element, and the subpixel may represent each light emitting element.

As shown in FIG. 4, a data driver Integrated Circuit (IC) 220 and a scan driver IC 210 for driving each light emitting element may be deposited on the substrate.

The data driver IC 220 may convert image data into analog voltage and supply the converted analog voltage to a data line, and the scan driver IC 210 may supply an analog voltage pulse waveform to a scan line according to a control signal.

Because the data driver IC 220 is required to determine which light emitting element to drive among the light emitting elements connected to the data line, the data driver IC 220 requires relatively high output current precision and low current driving capacity.

In contrast, the scan driver IC 210 requires a relatively high current driving capacity and relatively low output current precision.

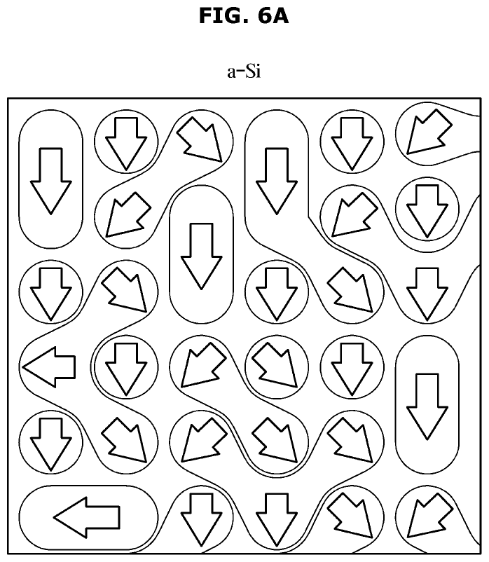

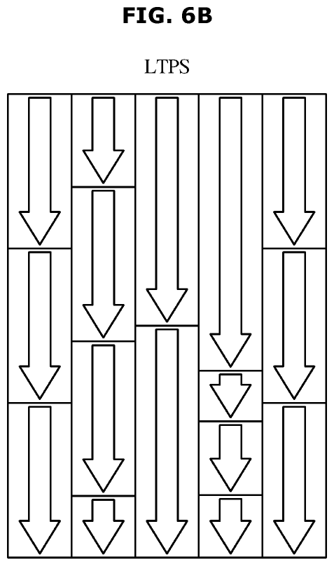

Accordingly, by manufacturing a Thin Film Transistor (TFT) included in the data driver IC 220 and a TFT included in the scan driver IC 210 in different processes suited to each of the drivers, the display apparatus may be driven more efficiently, which is described with reference to FIG. 6.

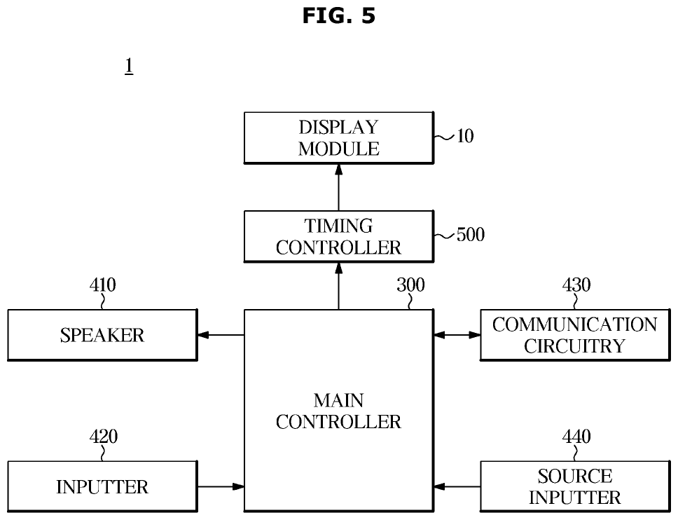

FIG. 5 is a control block diagram illustrating a display apparatus according to an embodiment.

The display apparatus 1 according to an embodiment may include the display module 10, a main controller 300 and a timing controller 500 that controls the display module 10, a communication circuitry 430 that communicates with an external device, a source inputter 440 that receives a source image, a speaker 410 that outputs sound, and an inputter 420 that receives a command for controlling the display apparatus 1 from a user.

The inputter 420 may include a button or a touch pad provided on an area of the display apparatus 1, and in a case where a display panel is implemented as a touch screen, the inputter 420 may include a touch pad disposed on a front surface of the display panel. The inputter 420 may also include a remote control.

The inputter 420 may receive various commands from the user for controlling the display apparatus 1, such as turning the display apparatus 1 on/off, adjusting volume, changing channels, modifying a screen, and adjusting various settings.

The speaker 410 may be provided in one area of the body 20, or a separate speaker module physically separated from the body 20 may be further provided.

The communication circuitry 430 may communicate with a relay server or other electronic devices to exchange required data. The communication circuitry 430 may employ at least one communication method from among wireless communication methods such as 3^{rd} Generation (3G), 4^{th} Generation (4G), Wireless Local Area Network (LAN), Wi-Fi, Bluetooth, Zigbee, Wi-Fi Direct (WFD), Ultra-Wideband (UWB), Infrared Data Association (IrDA), Bluetooth Low Energy (BLE), Near Field Communication (NFC), and Z-Wave. The communication circuitry 430 may also employ wired communication methods such as a Peripheral Component Interconnect (PCI), PCI-express, Universal Serial Bus (USB), and the like.

The source inputter 440 may receive a source signal input from a set-top box, USB, antenna, and the like. Accordingly, the source inputter 440 may include at least one selected from a group of source input interfaces including a High Definition Multimedia Interface (HDMI) cable port, USB port, antenna, and the like.

The source signal received by the source inputter 440 may be processed by the main controller 300 and converted into a form that may be output from the display panel and speaker 410.

The main controller 300 and the timing controller 500 may include at least one memory storing programs and data for performing operations to be described later, and at least one processor executing the stored programs.

The main controller 300 may process the source signal input through the source inputter 440 to generate an image signal corresponding to the input source signal.

For example, the main controller 300 may include a source decoder, scaler, image enhancer, and graphics processor. The source decoder may decode the source signal compressed in a form such as Moving Picture Experts Group (MPEG), and the scaler may output image data in a desired resolution through resolution conversion.

The image enhancer may improve the image quality of image data by applying various correction techniques. The graphics processor may classify pixels of image data into RGB data and may output a control signal such as a syncing signal for display timing on the display panel. That is, the main controller 300 may output image data and a control signal corresponding to the source signal.

The above-described operations of the main controller 300 are merely examples applicable to the display apparatus 1, and may further perform other operations or some of the aforementioned operations may be omitted.

The image data and the control signal output from the main controller 300 may be transmitted to the timing controller 500.

The timing controller 500 may convert the image data transmitted from the main controller 300 into image data in a form that may be processed by the driver IC, and may generate various control signals such as a timing control signal required to display the image data on the display panel.

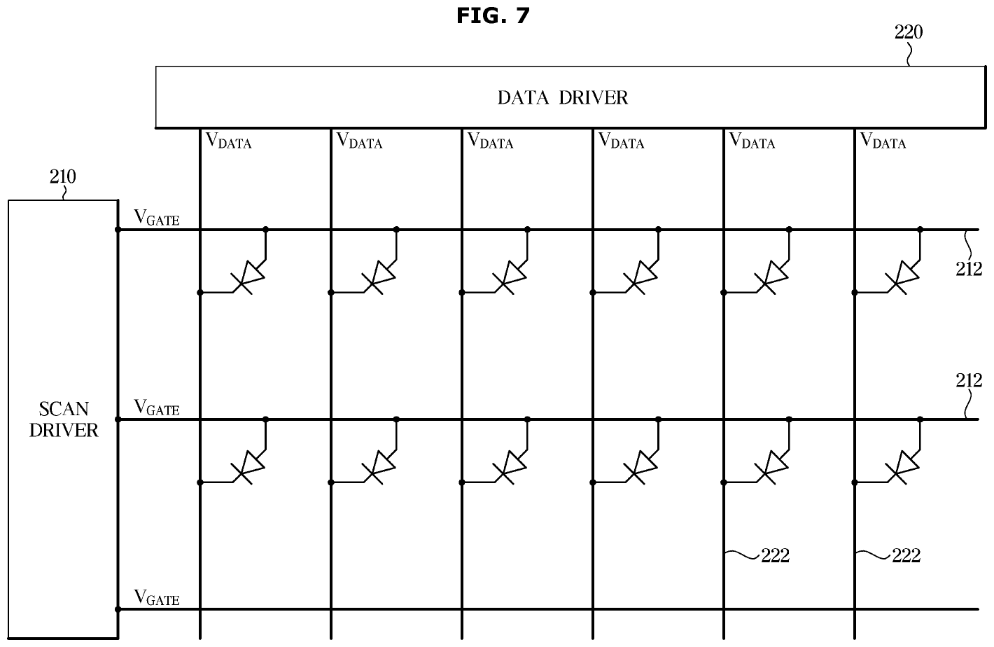

FIGS. 6A and 6B are diagrams illustrating electron mobility depending on a TFT manufacturing process according to an embodiment. FIG. 7 is a diagram illustrating a connection relationship among a data driver, a scan driver, and a light emitting element according to an embodiment.

As described above, the display apparatus 1 may be driven more efficiently by manufacturing a TFT included in the data driver IC 220 and a TFT included in the scan driver IC 210 in different processes suited to characteristics of each driver.

The data driver IC 220 requires relatively high output current precision and low current driving, while the scan driver IC 210 requires relatively high current driving and low output current precision. Based on the above, each TFT may be manufactured using different processes.

A TFT is an electronic circuit component made of semiconductors, and may function as a valve to regulate a flow of current.

In a TFT, after an active layer that allows current flow is formed on a substrate, adjusting a gate voltage moves electrons (holes) from a source to a drain through the active layer. The gate serves as a valve that regulates the current flowing through the active layer, and the source and drain exchange electrons.

TFTs may be classified into Amorphous Silicon (a-Si) and Low-Temperature polycrystalline silicon (LTPS) depending on the material. The a-Si refers to “amorphous silicon”, and the LTPS refers to “low-temperature polycrystalline silicon”. In the LTPS, electrons travel faster than in a-Si TFT, thereby implementing a high-speed circuit and delivering the required current in a short period of time. Accordingly, small transistors may be manufactured.

That is, as shown in FIG. 6A, the molecular arrangement of a-Si is disordered, and thus the electron movement speed is relatively slow.

The LTPS as shown in FIG. 6B is obtained by recrystallizing silicon molecules by applying a laser (Excimer laser) to a-Si. Disordered silicon is transformed into a crystalline structure and is arranged in a regular pattern, enabling a relatively fast electron movement speed.

According to the above characteristics, the data driver IC 220 that requires high output current precision and low current driving may include an a-Si TFT.

In addition, the scan driver IC 210 that requires relatively high current driving may include an LTPS TFT to enable high current driving according to high electron mobility.

Referring to FIG. 7, the display apparatus 1 may include a plurality of pixels arranged in a two-dimensional matrix on a substrate, a plurality of scan lines 212 and data lines 222 connected to the plurality of pixels P, the scan driver IC 210 that transmits a scan signal to the plurality of scan lines 212 and includes at least one first TFT, and the data driver IC 220 that transmits a data signal to the plurality of data lines 222 and includes at least one second TFT.

Here, the first TFT and the second TFT may be different types, as described above.

The first TFT may include an LTPS TFT, thereby having higher electron mobility than the second TFT. The second TFT may include an a-Si TFT, thereby having a higher accuracy in selecting a pixel to supply current than the first TFT.

As described above, by depositing the data driver IC 220 and the scan driver IC 210 in different manufacturing processes, a driving efficiency of a light emitting element may be increased and a production complexity of the display apparatus may be reduced.

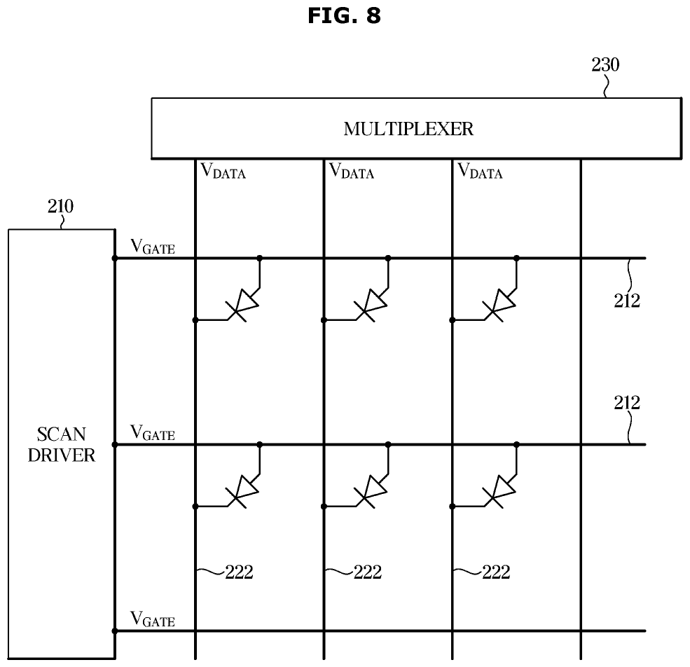

FIG. 8 is a diagram illustrating a display apparatus including a multiplexer according to an embodiment.

The display apparatus 1 may further include a multiplexer 230 to transmit a signal of the data driver IC 220 to one of at least three subpixels between the data driver IC 220 and the plurality of data lines 222.

In a case where a signal applied from the data driver IC 220 is transmitted to each pixel connected to the plurality of data lines 222, wiring may become complex.

Accordingly, the signal applied from the data driver IC 220 may be received by the multiplexer 230 through one wiring, and the multiplexer 230 may transmit the signal to required pixels among a plurality of subpixels, thereby reducing the number of wirings on the substrate.

According to an embodiment, the display apparatus may include a substrate; a plurality of pixels arranged in a two-dimensional matrix on the substrate: a plurality of scan lines connected in the plurality of pixels: a scan driver IC configured to transmit a scan signal to the plurality of scan lines, and including at least one first TFT: a plurality of data lines configured to be connected in the plurality of pixels; and a data driver IC configured to transmit a data signal to the plurality of data lines, and including at least one second TFT. The first TFT and the second TFT may be different types.

According to the disclosure, by depositing the data driver IC and the scan driver IC in different manufacturing processes, a driving efficiency of a light emitting element may be increased and production complexity of the display apparatus may be reduced.

The first TFT may have higher electron mobility than the second TFT.

According to the disclosure, by increasing electron mobility of a TFT of the scan driver, high current driving of the scan driver may be facilitated.

The second TFT may have a higher accuracy in selecting a pixel to supply a current than the first TFT.

According to the disclosure, low current driving of the data driver may be facilitated.

The first TFT may include a Low-Temperature Polycrystalline Silicon (LTPS) TFT.

The second TFT may include an Amorphous Silicon (a-Si) TFT.

Each of the plurality of pixels may include at least three subpixels that output different colors, and the display apparatus may further include a multiplexer to transmit a signal of the data driver IC to one of the at least three subpixels between the data driver IC and the plurality of data lines.

According to the disclosure, by transmitting/receiving a signal by using the multiplexer, the number of wirings on the substrate may be reduced.

Each of the plurality of pixels may include a red light emitting element, a green light emitting element, and a blue light emitting element.

According to the disclosure, by depositing the data driver IC and the scan driver IC in different manufacturing processes, a driving efficiency of a light emitting element may be increased and production complexity of the display apparatus may be reduced.

In addition, by transmitting/receiving a signal by using the multiplexer, the number of wirings on the substrate may be reduced.

Aspects of the disclosed embodiments may be implemented in the form of a recording medium that stores instructions executable by a computer. The instructions may be stored in the form of program codes, and when executed by a processor, the instructions may create a program module to perform operations of the disclosed embodiments. The recording medium may be implemented as a computer-readable recording medium.

The computer-readable recording medium may include all kinds of recording media storing instructions that can be interpreted by a computer. For example, the computer-readable recording medium may be a Read Only Memory (ROM), a Random Access Memory (RAM), a magnetic tape, a magnetic disk, a flash memory, an optical data storage device, etc.

Although the disclosure has been shown and described in relation to specific embodiments, it would be appreciated by those skilled in the art that changes and modifications may be made in these embodiments without departing from the principles and scope of the disclosure, the scope of which is defined in the claims and their equivalents.

What is claimed is:

1. A display apparatus comprising:
a substrate;
a plurality of pixels arranged in a two-dimensional matrix on the substrate;
a plurality of scan lines connected to the plurality of pixels;
a scan driver Integrated Chip (IC) configured to transmit a scan signal to the plurality of scan lines;
a plurality of data lines connected to the plurality of pixels; and
a data driver IC configured to transmit a data signal to the plurality of data lines,
wherein the scan driver IC comprises at least one first Thin Film Transistor (TFT), the data driver IC comprises at least one second TFT, and the at least one first TFT and the at least one second TFT are different types.

2. The display apparatus of claim 1, wherein the at least one first TFT is configured to have a higher electron mobility than the at least one second TFT.

3. The display apparatus of claim 1, wherein the at least one second TFT is configured to have a higher accuracy in selecting a pixel among the plurality of pixels to supply a current than the at least one first TFT.

4. The display apparatus of claim 1, wherein the at least one first TFT comprises a Low-Temperature Polycrystalline Silicon (LTPS) TFT.

5. The display apparatus of claim 4, wherein the at least one second TFT comprises an Amorphous Silicon (a-Si) TFT.

6. The display apparatus of claim 1,
wherein each pixel of the plurality of pixels comprises at least three subpixels configured to output different colors, and
wherein the display apparatus further comprises a multiplexer configured to transmit a signal from the data driver IC to at least one of the at least three subpixels of each pixel of the plurality of pixels via the plurality of data lines.

7. The display apparatus of claim 6, wherein each of the plurality of pixels further comprises a red light emitting element, a green light emitting element, and a blue light emitting element.

8. A display apparatus comprising:
a substrate;
a plurality of pixels arranged in a two-dimensional matrix on the substrate, wherein each pixel of the plurality of pixels comprises a plurality of subpixels configured to output different colors;
a plurality of scan lines connected to the plurality of pixels;
a scan driver Integrated Chip (IC) connected to the plurality of scan lines and configured to transmit a scan signal to the plurality of pixels via the plurality of scan lines;
a plurality of data lines configured connected to the plurality of pixels; and
a data driver IC connected to the plurality of data lines and configured to transmit a data signal to the plurality of pixels via the plurality of data lines,
wherein the scan driver IC comprises at least one first Thin Film Transistor (TFT), the data driver IC comprises at least one second TFT, and the at least one first TFT and the at least one second TFT are different types.

9. The display apparatus of claim 8, wherein the at least one first TFT is configured to have a higher electron mobility than the at least one second TFT.

10. The display apparatus of claim 9, wherein the at least one second TFT is configured to have a higher accuracy in selecting a pixel among the plurality of pixels to supply a current than the at least one first TFT.

11. The display apparatus of claim 8, wherein the at least one first TFT comprises a Low-Temperature Polycrystalline Silicon (LTPS) TFT.

12. The display apparatus of claim 11, wherein the at least one second TFT comprises an Amorphous Silicon (a-Si) TFT.

13. The display apparatus of claim 10,
wherein the display apparatus further comprises a multiplexer configured to transmit a signal from the data driver IC to at least one of the plurality of subpixels of each pixel of the plurality of pixels via the plurality of data lines.

14. The display apparatus of claim 13, wherein each of the plurality of pixels further comprises a red light emitting element, a green light emitting element, and a blue light emitting element.

15. A display apparatus comprising:
a substrate;
a plurality of pixels arranged in a two-dimensional matrix on the substrate, wherein each pixel of the plurality of pixels comprises a plurality of subpixels configured to output different colors;
a plurality of scan lines connected to the plurality of pixels;
a scan driver Integrated Chip (IC) connected to the plurality of scan lines and configured to transmit a scan signal to the plurality of pixels via the plurality of scan lines;
a plurality of data lines configured connected to the plurality of pixels;
a data driver IC connected to the plurality of data lines and configured to transmit a data signal to the plurality of pixels via the plurality of data lines; and
a multiplexer configured to transmit a signal from the data driver IC to at least one of the plurality of subpixels of each pixel of the plurality of pixels via the plurality of data lines,
wherein the scan driver IC comprises at least one first Thin Film Transistor (TFT), the data driver IC comprises at least one second TFT, and the at least one first TFT and the at least one second TFT are different types.

16. The display apparatus of claim 15, wherein the at least one first TFT is configured to have a higher electron mobility than the at least one second TFT.

17. The display apparatus of claim 15, wherein the at least one second TFT is configured to have a higher accuracy in selecting a pixel among the plurality of pixels to supply a current than the at least one first TFT.

18. The display apparatus of claim 15, wherein the at least one first TFT comprises a Low-Temperature Polycrystalline Silicon (LTPS) TFT.

19. The display apparatus of claim 15, wherein the at least one second TFT comprises an Amorphous Silicon (a-Si) TFT.

20. The display apparatus of claim 15, wherein each of the plurality of pixels further comprises a red light emitting element, a green light emitting element, and a blue light emitting element.
